(19) United States
(12) Patent Application Publication
(10) Pub. No.: US 2026/0344251 A1
(43) Pub. Date: Oct. 29, 2026

(54) DISPLAY DEVICE

(71) Applicant: LG Display Co., Ltd., Seoul (KR)

(72) Inventor: Junyang MAENG, Paju-si (KR)

(73) Assignee: LG Display Co., Ltd., Seoul (KR)

(21) Appl. No.: 19/659,522

(22) Filed: Apr. 27, 2026

(30) Foreign Application Priority Data
Apr. 28, 2025 (KR) 10-2025-0055115

(51) Int. Cl. H10K 59/80; H10K 102/00

(52) U.S. Cl. CPC H10K 59/871; H10K 59/8793; H10K 2102/311

(57) ABSTRACT

A display device can include a display panel and a backplate layer disposed on a lower surface of the display panel. The backplate layer can include an air gap formed therein, where the air gap is completely surrounded by the backplate layer. The backplate layer can further include a first base layer, a second base layer facing the first base layer, and an elastic layer disposed between the first base layer and the second base layer.

### CROSS-REFERENCE TO RELATED APPLICATIONS

This application claims priority to and the benefit of Korean Patent Application No. 10-2025-0055115, filed in the Republic of Korea on Apr. 28, 2025, the disclosure of which is expressly incorporated by reference in its entirety.

### BACKGROUND

### Technical Field

Embodiments of the present disclosure relate to a display device.

### Discussion of the Related Art

As the information society develops, the demand for display devices that display images is increasing, and various types of display devices, such as liquid crystal displays (LCDs) and organic light-emitting diode displays (OLEDs), are being utilized.

The display device includes a plurality of pixels, and a plurality of switching elements are provided to drive and control the pixels.

### SUMMARY OF THE DISCLOSURE

Accordingly, one object of the embodiments of the present disclosure is to address the above-noted disadvantages of the related art, and to provide a display device that can prevent damage to a display panel.

The objects of the present disclosure are not limited to those mentioned above, and other technical objects can be inferred from the embodiments described below.

To accomplish the objects of the present disclosure, according to an embodiment of the present disclosure, a display device can include a display panel and a backplate layer disposed on a lower surface of the display panel. The backplate layer can include an air gap formed therein, the air gap being completely surrounded by the backplate layer.

To accomplish the objects of the present disclosure, a display device according to another embodiment can include a display panel comprising a main region, a sub-region, and a bending region; a first backplate layer disposed on a lower surface of the main region of the display panel; a second backplate layer disposed on a lower surface of the sub-region of the display panel; and a mold portion disposed on a lower surface of the bending region of the display panel. The first backplate layer or the second backplate layer can include an air gap therein, and the mold portion can contact the first backplate layer.

Specific details of other embodiments of the present disclosure are included in the detailed description and the drawings.

According to the embodiments of the present disclosure, since a backplate layer has an airgap therein, the backplate layer absorbs an impact which can be caused by foreign substances remaining on a surface of a display panel during a process of attaching the backplate layer to the display panel, thereby preventing or minimizing damage to the display panel.

In the embodiments of the present disclosure, since a backplate layer has an airgap therein, the backplate layer absorbs external force, thereby preventing or minimizing damage to a display panel.

The embodiments of the present disclosure can provide a low-power display device capable of improving a lifespan thereof.

However, the effects obtainable from the present disclosure are not limited to the effects mentioned above, and other unmentioned effects will be clearly understood by those skilled in the art from the description below.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view of a display device according to an embodiment of the present disclosure;

FIG. 2 is a cross-sectional view showing the display panel according to FIG. 1 in a bent state according to an example of the present disclosure;

FIG. 3 is a plan view showing the display device according to FIG. 1 in a bent state according to an example of the present disclosure;

FIG. 4 is a cross-sectional view taken along line B-B' of FIG. 3 according to an example of the present disclosure;

FIG. 5 is a cross-sectional view taken along line C-C' of FIG. 3 according to an example of the present disclosure;

FIG. 6 is a cross-sectional view taken along line A-A' of FIG. 1 according to an example of the present disclosure;

FIG. 7 is a schematic plan view of a display device according to an embodiment of the present disclosure;

FIG. 8 is a cross-sectional view taken along line D-D' of FIG. 7 according to an example of the present disclosure;

FIGS. 9 and 10 are cross-sectional views showing the display device absorbing impact from a foreign substance according to an embodiment of the present disclosure;

FIG. 11 is a cross-sectional view showing the absorption of external force by a display device according to one embodiment of the present disclosure; and

FIGS. 12 and 13 are cross-sectional views showing the absorption of external force generated during the process of attaching a printed circuit board by a display device according to one embodiment of the present disclosure.

### DETAILED DESCRIPTION OF THE EMBODIMENTS

Hereinafter, example embodiments of the present disclosure will be described with reference to the drawings.

Like reference numerals refer to like elements throughout. In the drawings, the thickness, ratio, and dimensions of elements can be exaggerated for effective description of technical contents. The scale of the elements shown in the drawings is not limited to the scale shown in the drawings, as different scales are used for convenience of description.

In the present disclosure, when an element (or region, layer, portion, etc.) is referred to as being "on," "connected to," or "coupled to" another element, it means that it can be directly connected/coupled to the other element or that a third intervening element can be disposed therebetween. Further, the term “can” fully encompasses all the meanings and coverages of the term “may.”

The term "and/or" includes any and all combinations of one or more of the associated configurations can define.

Terms such as "first," "second," etc., can be used to describe various elements, but the elements are not limited by these terms. These terms are only used to distinguish one element from another. For example, a first element could be termed a second element, and similarly, a second element could be termed a first element, without departing from the scope of the present example embodiments. The singular forms are intended to include the plural forms as well, unless the context clearly indicates otherwise.

Terms such as "below," "on the lower side," "above," and "on the upper side" are used to describe the relationship between components illustrated in the drawings. These terms are relative concepts and are described based on the directions shown in the drawings. For example, unless "directly" or "immediately" is used, one or more other parts can be positioned between two parts. Spatially relative terms, such as "below," "beneath," "lower," "above," and "upper," can be used to easily describe the relationship between one element or component and another element or component as illustrated in the drawings. It should be understood that the spatially relative terms encompass different directions of the device in use or operation in addition to the direction shown in the drawings. For instance, if the device shown in the drawings is turned over, an element described as "below" or "beneath" another element can be placed "above" the other element. Accordingly, the example term "below" can encompass both the downward and upward directions.

The terms such as "comprises," "comprising," "includes," "including," "has," or "having" are intended to specify the presence of features, numbers, steps, operations, elements, components, or combinations thereof described in the disclosure, and should be understood not to preclude the presence or addition of one or more other features, numbers, steps, operations, elements, components, or combinations thereof.

Each feature of the various embodiments of the present disclosure can be partially or entirely combined or united with each other, and various technical interworking and driving are possible. Each embodiment can be implemented independently of each other or can be implemented together in an associated relationship.

Hereinafter, a display device of the present disclosure will be described with reference to the accompanying drawings and embodiments. All the components of each display device/apparatus according to all embodiments of the present disclosure are operatively coupled and configured.

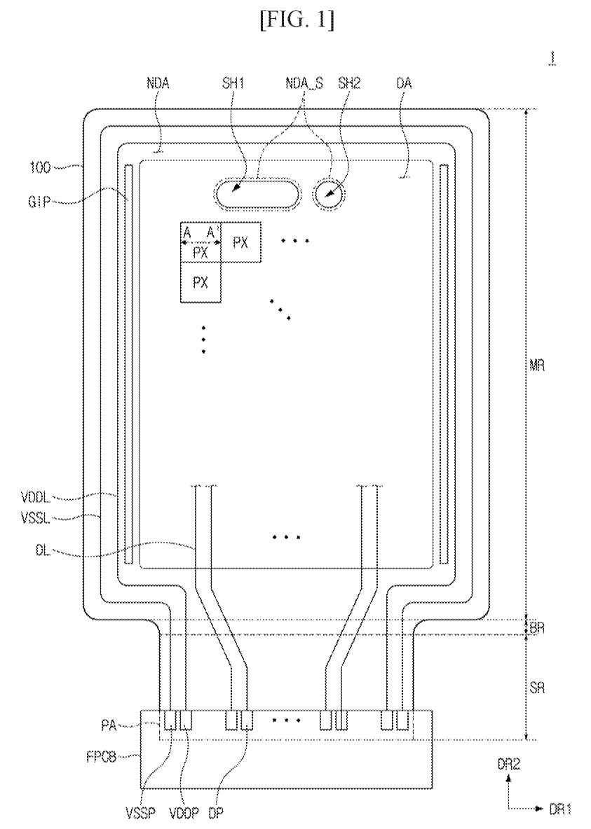

FIG. 1 is a plan view of a display device according to an embodiment of the present disclosure.

Referring to FIG. 1, a display device 1 according to an embodiment of the present disclosure can include a display panel 100. The display panel 100 can include a display area (DA) including a plurality of pixels (PX), and a non-display area (NDA) surrounding the display area DA. The NDA can surround the DA entirely or only in part(s). The planar shape of the display area DA can be a rectangular shape. However, the present disclosure is not limited thereto, and the planar shape of the display area DA can be a square, a circle, an ellipse, or other polygons. For example, the display area DA can have a rectangular shape with rounded corners, but is not limited thereto, and can have a rectangular shape with sharp corners.

In the embodiments of the present disclosure, a first direction (DR1) and a second direction DR2 are different directions intersecting each other, and represent, for example, directions intersecting perpendicularly in a plan view. In FIG. 1, the first direction DR1 can generally coincide with an extension direction of short sides of the display panel 100, and the second direction (DR2) can coincide with an extension direction of long sides of the display panel 100. However, the directions mentioned in the embodiments should be understood as referring to relative directions, and the embodiments of the present disclosure are not limited to the mentioned directions.

The display area DA can include short sides extending along the first direction DR1 and long sides extending along the second direction DR2. The non-display area NDA can surround the display area DA. The non-display area NDA can be disposed on one side and the other side of the display area DA in the first direction DR1, and on one side and the other side thereof in the second direction DR2.

The display panel 100 can further include a sensor non-display area (NDA_S) and sensor holes (SH1) and (SH2) surrounded by the sensor non-display area NDA_S. The sensor holes SH1 and SH2 can be surrounded by the display area DA in a plan view. For example, there can be two sensor holes SH1 and SH2 as shown in FIG. 1, but embodiments of the present disclosure are not limited thereto. For example, a single sensor hole can be provided. The two sensor holes SH1 and SH2 can include a sensor hole in which an infrared sensor is disposed and a sensor hole in which a camera sensor is disposed, respectively, but embodiments of the present disclosure are not limited thereto. The sensor non-display area NDA_S can be disposed between the sensor holes SH1 and SH2 and the display area DA. The sensor non-display area NDA_S can completely surround the sensor holes SH1 and SH2. The pixels PX may not be disposed in the sensor non-display area NDA_S. In some embodiments of the present disclosure, the sensor holes SH1 and SH2 can be omitted, and an infrared sensor or a camera sensor can be disposed in the display area DA. In this case, the number of pixels PX per unit area of the display area DA where the infrared sensor or the camera sensor is disposed can be less than the number of pixels PX per unit area of the display area DA where the infrared sensor or the camera sensor is not disposed. For example, the display area DA where the infrared sensor or the camera sensor is disposed can further include a transmissive area.

A gate driver (GIP) can be disposed in the non-display area (NDA) located on one side of the first direction (DR1) of the display area (DA) and the non-display area (NDA) located on the other side of the first direction (DR1) of the display area (DA). The low-potential voltage line (VSSL) can be disposed outside the gate driver (GIP) on the non-display area (NDA). For example, as illustrated in FIG. 1, the low-potential voltage line (VSSL) can extend from a printed circuit board (FPCB), pass through the sub-region (SR) and the bending region (BR), be disposed outside the gate driver (GIP) on the non-display area (NDA), and surround the display area (DA). A high-potential voltage line (VDDL) can be disposed outside the gate driver (GIP) on the non-display area (NDA). The high-potential voltage line (VDDL) can be disposed between the low-potential voltage line (VSSL) and the gate driver (GIP).

The non-display area (NDA) located on the other side of the second direction (DR2) of the display area (DA) can extend further in the second direction (DR2) from the central portion of the other side of the second direction (DR2) of the display area (DA). A width in the first direction (DR1) of the non-display area (NDA) extending further in the second direction (DR2) from the central portion of the other side of the second direction (DR2) of the display area (DA) can be smaller than a width in the first direction (DR1) of a non-display area (NDA) adjacent to the other side of the second direction (DR2) of the display area (DA).

A display device 1 can include a main region (MR), a sub region (SR), and a bending region (BR) between the main region (MR) and the sub region (SR). The above-described display area (DA) and the non-display area (NDA) surrounding the display area (DA) on four sides constitute the main region (MR), and a portion extending further in the second direction (DR2) from the central portion of the other side of the second direction (DR2) of the display area (DA) can constitute a bending region (BR) and a sub region (SR). The bending region (BR) can be arranged between the sub region (SR) and the main region (MR). The sub region (SR) can include a pad area (PA). In some embodiments of the present disclosure, the sub region (SR) can include a first pad area and a second pad area located at the other end of the sub region (SR) in the second direction (DR2), and a data driver can be attached to the first pad area, and a printed circuit board (FPCB), which will be described later, can be attached to the second pad area. Hereinafter, a description will be given focusing on a case where only the pad area (PA) is arranged. The display device 1 can further include a printed circuit board (FPCB). A printed circuit board (FPCB) can be attached to the pad area (PA). The plurality of pads, each connected to the printed circuit board (FPCB), can be arranged on the pad area (PA). The data driver can be arranged on the printed circuit board (FPCB), and the data driver can be provided in the form of a driver chip (IC).

The plurality of pads can be arranged on the pad area (PA). The plurality of pads can include power pads (low-potential voltage pads (VSSP), high-potential voltage pads (VDDP)), and data voltage pads (DP). Data voltage pads (DP) can be arranged in the center of the pad area (PA), and low-potential voltage pads (VSSP) and high-potential voltage pads (VDDP) can be arranged on the periphery of the pad area (PA). The high-potential voltage pad (VDDP) can be arranged between the low-potential voltage pad (VSSP) and the data voltage pad (DP). Each power pad (VDDP, VSSP) can be positioned on the left and right sides of the pad area (PA). The data voltage pad (DP) can be connected to a data line (DL). The data line (DL) can be connected to each pixel (PX) in the display area (DA).

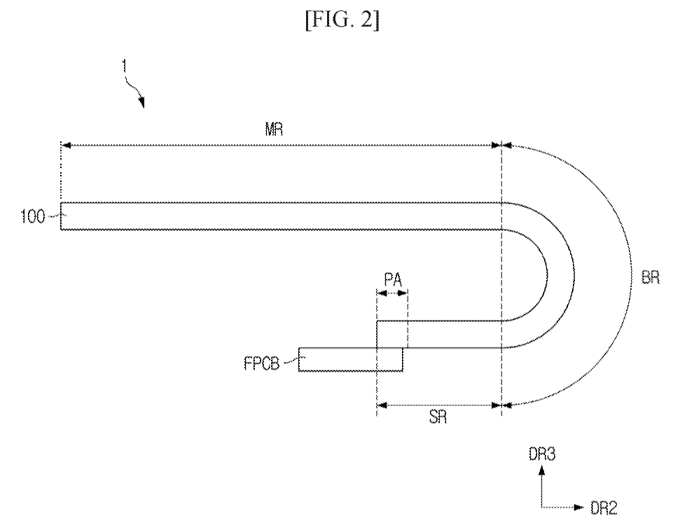

FIG. 2 is a cross-sectional view illustrating a bent state of the display panel shown in FIG. 1.

Referring to FIG. 2, the bending region (BR) of the display panel 100 of the display device 1 according to one embodiment of the present disclosure can be bent in the thickness direction (or the third direction (DR3)). Accordingly, the main region (MR) and the sub-region (SR) can overlap in the thickness direction. The display panel (100) can be bent such that the lower surface of the main region (MR) and the upper surface of the sub-region (SR) face each other. A printed circuit board (FPCB) can be attached to an end of the sub-region (SR).

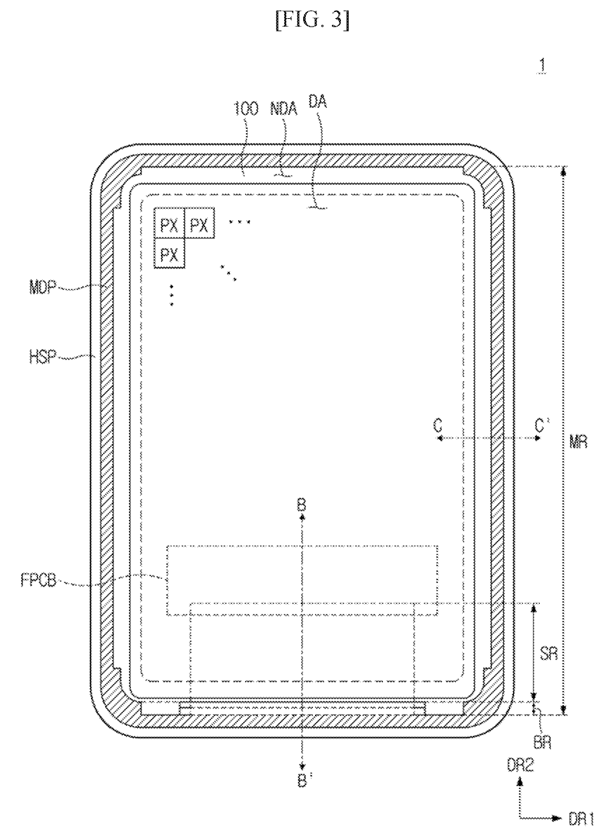

FIG. 3 is a plan view illustrating a bent state of the display device according to FIG. 1.

Referring to FIG. 3, the display device 1 can further include a mold portion (MDP). The mold portion (MDP) can be located on the upper short side of the display panel 100 in the second direction (DR2), the left and right long sides of the display panel 100, the corner side of the display panel 100, and the lower short side of the display panel 100 in the second direction (DR2).

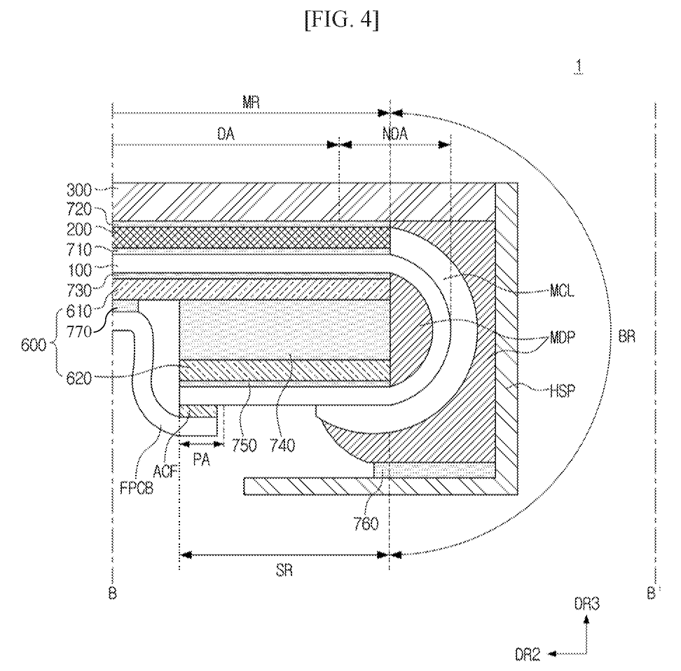

FIG. 4 is a cross-sectional view taken along the line B-B’ of FIG. 3.

Referring to FIGS. 3 and 4, the display device 1 can include the display panel 100, a polarizing layer 200, a cover window 300, a backplate layer 600, bonding layers 710, 720, 730, 740, 750, 760, 770, a cover layer (MCL), a mold portion (MDP), and a housing (HSP).

The bending region (BR) of the display panel 100 can have a curved shape and can be bent in the thickness direction. The main region (MR) and the sub-region (SR) of the display panel 100 can overlap each other.

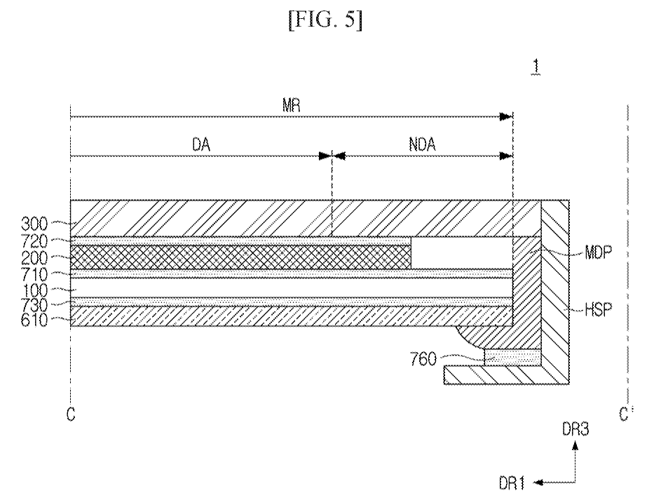

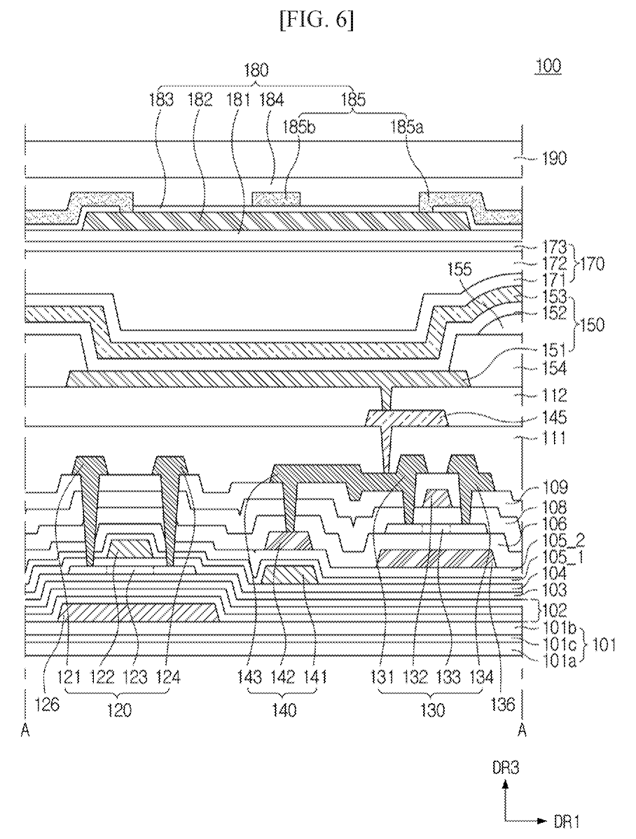

The polarizing layer 200 can be disposed on the main region (MR) of the display panel 100. The polarizing layer 200 can polarize light emitted from the display panel 100 at a polarization angle. The polarizing layer 200 can emit light polarized at the polarization angle to the outside. The polarizing layer 200 can have a function of blocking reflection of light except for light polarized at the polarization angle among external light. The polarizing layer 200 can include a first phase retardation layer, a second phase retardation layer on the first phase retardation layer, and a polarizing layer on the second phase retardation layer. In FIGS. 5 and 6, the polarizing layer 200 and the display panel 100 are illustrated as being separate from each other, but the present disclosure is not limited thereto, and the polarizing layer 200 can be included in the display panel 100. In some embodiments of the present disclosure, the polarizing layer 200 can be omitted and a color filter can be disposed.

A cover window 300 can be disposed on the polarizing layer 200. The cover window 300 can be formed of a glass material, such as glass or quartz, but the embodiments of the present disclosure are not limited thereto, and can be formed of a plastic material. The cover window 300 can be disposed on the display panel 100, thereby protecting components disposed below the cover window 300 from the outside. The cover window 300 can be a cover layer formed by chemical strengthening, but the embodiments of the present disclosure are not limited thereto. The cover window 300 can be a cover layer, a window cover, or a cover member. The embodiments of this disclosure are not limited thereto.

The cover window 300 can protect the components disposed under the cover window 300 from the outside, but as described, since the cover window 300 is formed of a glass material, the cover window 300 can be damaged by an external force, creating glass fragments. The glass fragments can scatter to the outside of the display device 1. According to an embodiment of the present disclosure, in order to prevent scattering of glass fragments due to damage to the cover window 300 or to improve the durability of the cover window 300, the display device 1 can further include at least one other layer on the cover window 300. For example, the display device 1 can further include a film layer or a coating layer on the cover window 300, but the embodiments of the present disclosure are not limited thereto.

The side surface of the cover window 300 can protrude outward more than the side surface of the display panel 100. For example, the side surface of the cover window 300 can protrude further outward than the end of the bending region (BR) of the display panel 100, but the embodiments of the present disclosure are not limited thereto.

The backplate layer 600 can be disposed under the display panel 100. The backplate layer 600 can be disposed under the display panel 100 to support the display panel 100. The backplate layer 600 can include a material capable of supporting the display panel 100. For example, the backplate layer 600 can include polyethylene terephthalate (PET), polyimide (PI), or polycarbonate (PC), but the embodiments of the present disclosure are not limited thereto. The backplate layer 600 can maintain a constant curvature of the bending region (BR) when the display device 1 is bent, and can suppress wrinkles occurring on the upper surface of the display panel 100. As described below, the backplate layer 600 can include an air gap therein.

The backplate layer 600 can include a first backplate layer 610 on the main region (MR), and a second backplate layer 620 on the sub-region (SR). The first backplate layer 610 can be disposed between the main region (MR) of the display panel 100 and the plate layer, and the second backplate layer 620 can be disposed between the sub-region (SR) of the display panel 100 and the plate layer. The backplate layer 600 may not be disposed on the bending region (BR).

A fourth bonding layer 740 can be disposed between the first backplate layer 610 and the second backplate layer 620.

In some embodiments of the present disclosure, a plate layer can be further disposed between the first backplate layer 610 and the second backplate layer 620. The plate layer can comprise metal. For example, the plate layer can comprise stainless steel, but the embodiments of the present disclosure are not limited thereto.

Bonding layers can be disposed between the above-described members 100, 200, 300, 610, and 620. The bonding layers can include a first bonding layer 710, a second bonding layer 720, a third bonding layer 730, a fourth bonding layer 740, a fifth bonding layer 750, a sixth bonding layer 760 and a seventh bonding layer 770.

The first bonding layer 710 can connect or bond the display panel 100 and the polarizing layer 200.

The second bonding layer 720 can be disposed between the polarizing layer 200 and the cover window 300. The second bonding layer 720 can connect or bond the polarizing layer 200 and the cover window 300.

The third bonding layer 730 can be disposed between the first backplate layer 610 and the display panel 100. The third bonding layer 730 can connect or bond the first backplate layer 610 and the display panel 100.

The fourth bonding layer 740 can be disposed between the first backplate layer 610 and the second backplate layer 620. The fourth bonding layer 740 can connect or bond the first backplate layer 610 and the second backplate layer 620.

The fifth bonding layer 750 can be positioned between the second backplate layer 620 and the display panel 100 of the sub-region (SR). The fifth bonding layer 750 can connect or bond the second backplate layer 620 and the display panel 100.

The first bonding layer 710 and the second bonding layer 720 can each include a transparent adhesive, but the embodiments of the present disclosure are not limited thereto. For example, the transparent adhesive can be a transparent resin (OCR) or a transparent adhesive (OCA), but the embodiments of the present disclosure are not limited thereto. The third bonding layer 730, the fourth bonding layer 740, the fifth bonding layer 750, the sixth bonding layer 760, and the seventh bonding layer 770 can each include a pressure sensitive adhesive (PSA), but the embodiments of the present disclosure are not limited thereto.

A cover layer (MCL) can be disposed on one surface of the bending region (BR) of the display panel 100. The cover layer (MCL) can include a plastic material and can be coated on one surface of the bending region (BR) of the display panel 100 to cover the bending region (BR) of the display panel 100. A link line can be disposed on the bending region (BR). The cover layer (MCL) can protect the link line from external impact while preventing or minimizing moisture from penetrating into the link line. In addition, the cover layer (MCL) can serve to position the link line on the neutral plane when the bending region (BR) of the display panel 100 is bent into a curved shape having a constant radius of curvature. A neutral plane is formed within the bending region (BR) where the tensile force and the compressive force are zero, and the link line is positioned on the neutral plane, so that when the display panel 100 is bent, the link line receives a bending stress of zero, and thus the display panel 100 can be bent without being damaged by the bending stress.

The cover layer (MCL) can be in contact with the side surfaces of the polarizing layer 200 and the first bonding layer 710. The cover layer (MCL) can partially extend to the sub-region (SR). The cover layer (MCL) can expose the printed circuit board (FPCB).

The printed circuit board (FPCB) can be disposed in the pad area (PA) of the sub-region (SR). The printed circuit board (FPCB) can be electrically connected to pads on the display panel 100 via an anisotropic conductive film (ACF). The printed circuit board (FPCB) can be bonded to the lower surface of the first backplate layer 610 via the seventh bonding layer 770.

The mold portion (MDP) can be disposed on the cover layer (MCL). The mold portion (MDP) can include an organic material (e.g., resin), but the embodiments of the present disclosure are not limited thereto. The mold portion (MDP) can cover the outer surface of the bending region (BR) of the display panel 100 and, for example, can be in direct contact with the lower surface of the cover window 300. The mold portion (MDP) can also be in contact with the inner surface of the housing (HSP). The mold portion (MDP) can also be disposed on the inner side of the bending region (BR). The mold portion (MDP) can be in contact with the inner surface of the bending region (BR) and the side surfaces of the first and second backplate layers 610, 620.

The housing (HSP) can be disposed on the outermost side of the display device 1. A portion extending in the thickness direction (or third direction (DR3)) of the housing (HSP) can be in direct contact with the cover window 300 and the mold portion (MDP). A portion extending in the second direction (DR2) of the housing (HSP) can be bonded to the mold portion (MDP) via the sixth bonding layer 760.

FIG. 5 is a cross-sectional view taken along line C-C' of FIG. 3.

For example, FIG. 5 illustrates the main region (MR) including a display region (DA) and a non-display region (NDA). FIG. 5 illustrates a cross-sectional view of the right region (or a short side of one side in the first direction (DR1)) of the display device 1. The cross-sectional view of the right region of the display device 1 can be substantially identical to the cross-sectional views of the left region and the upper region of the display device 1.

Referring to FIGS. 3 and 5, the mold portion (MDP) can be in direct contact with the side surfaces of the display panel 100, and the side surfaces of the first backplate layer 610. The mold portion (MDP) can be bonded to the housing (HSP) via the sixth bonding layer 760. The mold portion (MDP) can be in contact with the lower surface of the cover window 300 and the inner surface of the housing (HSP).

According to the display device (1) according to one embodiment of the present disclosure, the mold portion (MDP) can include an organic material. The mold portion (MDP) can include an organic material that repeatedly contracts and expands depending on heat.

FIG. 6 is a cross-sectional view taken along line A-A' of FIG. 1.

Referring to FIG. 6, the display panel 100 can include a substrate 101, a buffer layer 102, a first thin film transistor 120, a second thin film transistor 130, a storage electrode 140, a light-emitting unit 150, an encapsulation unit 170, a touch unit 180, and an upper organic layer 190.

The substrate 101 can include one or more plastic materials. For example, the substrate 101 can be a multi-substrate 101a, 101b and 101c including multiple plastic materials such as polyimide, but is not limited thereto.

The buffer layer 102 can be disposed on the substrate 101. The buffer layer 102 can minimize or delay the diffusion of moisture or oxygen penetrating the substrate 101. The buffer layer 102 can be formed by alternately stacking silicon nitride (SiNx) and silicon oxide (SiOx) at least once, but the embodiments of the present disclosure are not limited thereto.

A first light-shielding layer 126 can be disposed between the substrate 101 and the buffer layer 102. The first light-shielding layer 126 can prevent light from transmitting through the first semiconductor layer 123 of the first thin film transistor 120. For example, the first semiconductor layer 123 can be disposed to overlap the first light-shielding layer 126. The first light-shielding layer 126 can be a single layer or multiple layers made of any one of molybdenum (Mo), aluminum (Al), chromium (Cr), nickel (Ni), neodymium (Nd), and copper (Cu), or an alloy thereof, but the embodiments of the present disclosure are not limited thereto.

A first insulating layer 103 can be disposed on the first light-shielding layer 126. The first insulating layer 103 can prevent a short circuit between the configuration of the first thin film transistor 120 and the first light-shielding layer 126. The first insulating layer 103 can be made of the same material as the buffer layer 102, but the embodiments of the present disclosure are not limited thereto. For example, the first insulating layer 103 can be made of an inorganic material such as silicon nitride (SiNx) or silicon oxide (SiOx), but the embodiments of the preset disclosure are not limited thereto.

A first thin film transistor 120 can be disposed on the first insulating layer 103. The first thin film transistor 120 can include a first source electrode 121, a first gate electrode 122, a first semiconductor layer 123, and a first drain electrode 124.

The first semiconductor layer 123 can be disposed on the first insulating layer 103. The first semiconductor layer 123 can include, but is not limited to, a metal oxide semiconductor such as IGZO (Indium-Gallium-Zinc Oxide), a silicon-based semiconductor material such as amorphous silicon, or polycrystalline silicon. The first semiconductor layer 123 can include a channel region, a source region, and a drain region.

The polycrystalline semiconductor layer has higher mobility than the amorphous semiconductor layer and the oxide semiconductor layer, and thus can have lower energy consumption and superior reliability. Accordingly, the driving transistor can be formed of the polycrystalline semiconductor layer.

The second insulating layer 104 can be disposed on the first semiconductor layer 123. The second insulating layer 104 can be made of the same material as the first insulating layer 103 and can prevent a short circuit between the first semiconductor layer 123 and other components of the first thin film transistor 120.

The first gate electrode 122 can be disposed on the second insulating layer 104. The first gate electrode 122 can be disposed on the second insulating layer 104 so as to overlap the channel region of the first semiconductor layer 123. The first gate electrode 122 can be disposed as a single layer or multiple layers including molybdenum (Mo), copper (Cu), titanium (Ti), aluminum (Al), chromium (Cr), gold (Au), nickel (Ni), neodymium (Nd), or compounds thereof. The first gate electrode 122 can be disposed together with a gate line.

The third insulating layer 105_1, 105_2 can be disposed on the first gate electrode 122. The third insulating layer 105_1, 105_2 can be formed of the same material as the first insulating layer 103 or the second insulating layer 104.

The first source electrode 121 and the first drain electrode 124 can be disposed on the third insulating layer 105_1, 105_2.

The first source electrode 121 and the first drain electrode 124 can be electrically connected to the first semiconductor layer 123 through a contact hole. The first source electrode 121 and the first drain electrode 124 can be formed of a metal material. For example, the first source electrode 121 and the first drain electrode 124 can be a single layer or multiple layers made of any one of molybdenum (Mo), aluminum (Al), chromium (Cr), gold (Au), titanium (Ti), nickel (Ni), neodymium (Nd), and copper (Cu), or an alloy thereof, but the embodiments of the present disclosure are not limited thereto.

The first source electrode 121 and the first drain electrode 124 can be arranged together with a data line. For example, the data line can be made of the same material as the first source electrode 121 and the first drain electrode 124, and can be formed on the same layer, but the embodiments of the present disclosure are not limited thereto.

The storage electrode 140 can be arranged spaced apart from the first thin film transistor 120. The storage electrode 140 can include a first storage electrode 141, a second storage electrode 142, and a third storage electrode 143.

The first storage electrode 141 can be placed on the same layer as the first gate electrode 122 and can be made of the same material, but the embodiments of the present disclosure are not limited thereto.

The second storage electrode 142 can be disposed on the first storage electrode 141. The second storage electrode 142 can be disposed on the third insulating layer 105_1, 105_2, and a capacitance can be formed using the third insulating layer 105_1, 105_2 between the first storage electrode 141 and the second storage electrode 142 as a dielectric. The second storage electrode 142 can be made of the same material as the first storage electrode 141, but the embodiments of the present disclosure are not limited thereto.

The second thin film transistor 130 can be disposed spaced apart from the first thin film transistor 120 and the storage electrode 140. The second thin film transistor 130 can include a second source electrode 131, a second gate electrode 132, a second semiconductor layer 133, and a second drain electrode 134.

The second light-shielding layer 136 can be disposed on the same layer as the second storage electrode 142.

Similar to the first light-shielding layer 126, the second light-shielding layer 136 can block light from reaching the second semiconductor layer 133, thereby extending the lifespan of the second thin film transistor 130. For example, the second semiconductor layer 133 can be disposed to overlap the second light-shielding layer 136.

A fourth insulating layer 106 can be disposed on the second light-shielding layer 136. The fourth insulating layer 106 can be made of the same material as, but is not limited to, the first insulating layer 103, the second insulating layer 104, or the third insulating layer 105_1, 105_2.

A second semiconductor layer 133 can be disposed on the fourth insulating layer 106. The second semiconductor layer 133 can include a source region, a drain region, and a channel region between the source and drain regions.

The second semiconductor layer 133 can include, but is not limited to, a metal oxide semiconductor such as IGZO (Indium-Gallium-Zinc Oxide), a silicon-based semiconductor material such as amorphous silicon, or polycrystalline silicon.

A fifth insulating layer 108 can be disposed on the second semiconductor layer 133. The fifth insulating layer 108 can be made of, but is not limited to, the same material as the first insulating layer 103, the second insulating layer 104, the third insulating layer 105_1, 105_2, or the fourth insulating layer 106.

The second gate electrode 132 can be disposed on the fifth insulating layer 108.

The second gate electrode 132 can be made of the same material as the first gate electrode 122. For example, the second gate electrode 132 can be formed as a single layer or multiple layers including molybdenum (Mo), copper (Cu), titanium (Ti), aluminum (Al), chromium (Cr), gold (Au), nickel (Ni), neodymium (Nd), or compounds thereof, but the embodiments of the present disclosure are not limited thereto.

A sixth insulating layer 109 can be disposed on the second gate electrode 132. The sixth insulating layer 109 can be made of the same material as the first insulating layer 103, the second insulating layer 104, the third insulating layer 105_1, 105_2, the fourth insulating layer 106, or the fifth insulating layer 108, but the embodiments of the present disclosure are not limited thereto.

The first source electrode 121, the first drain electrode 124, the third storage electrode 143, the second source electrode 131, and the second drain electrode 134 can be disposed on the sixth insulating layer 109.

The third storage electrode 143, the second source electrode 131, and the second drain electrode 134 can be made of the same material as the first source electrode 121 and the first drain electrode 124, and can be disposed on the same layer. For example, the third storage electrode 143, the second source electrode 131, and the second drain electrode 134 can be a single layer or multiple layers made of any one of molybdenum (Mo), aluminum (Al), chromium (Cr), gold (Au), titanium (Ti), nickel (Ni), neodymium (Nd), and copper (Cu), or an alloy thereof, but the embodiments of the present disclosure are not limited thereto.

The first thin film transistor 120 can be a switching transistor, and the second thin film transistor 130 can be a driving transistor, but the embodiments of the present disclosure are not limited thereto.

A first protective layer 111 can be disposed on the first source electrode 121 and the first drain electrode 124.

The first protective layer 111 can planarize the upper portion of the first thin film transistor 120 and protect the first thin film transistor 120. The first protective layer 111 can be formed of an organic material. For example, the first protective layer 111 can be formed of an organic material including, but not limited to, an acrylic resin, an epoxy resin, a phenolic resin, a polyamide resin, or a polyimide resin.

A second protective layer 112 can be disposed on the first protective layer 111. The second protective layer 112 can be formed of the same material as the first protective layer 111, but the embodiments of the present disclosure are not limited thereto.

A connection electrode 145 can be disposed between the first protective layer 111 and the second protective layer 112.

The connection electrode 145 can electrically connect the second thin film transistor 130 and the light-emitting unit 150. The connection electrode 145 can be formed of the same material as the first source electrode 121 and the first drain electrode 124, but the embodiments of the present disclosure are not limited thereto.

The connection electrode 145 can be a single layer or multiple layers made of one or an alloy of molybdenum (Mo), aluminum (Al), chromium (Cr), gold (Au), titanium (Ti), nickel (Ni), neodymium (Nd), and copper (Cu), but the embodiments of the present disclosure are not limited thereto.

The light-emitting unit 150 can be disposed on the second protective layer 112. The light-emitting unit 150 can include a first electrode 151, an organic layer 152, and a second electrode 153. The first electrode 151 can function as an anode, and the second electrode 153 can function as a cathode, but the embodiments of the present disclosure are not limited thereto.

The first electrode 151 can be disposed on the second protective layer 112. The first electrode 151 can be electrically connected to the second thin film transistor 130 through a contact hole formed in the second protective layer 112. The first electrode 151 can be a reflective electrode that reflects light, but the embodiments of the present disclosure are not limited thereto. The first electrode 151 can include a highly reflective metal material such as a laminated structure of aluminum (Al) and titanium (Ti) (Ti/Al/Ti), a laminated structure of aluminum (Al) and indium tin oxide (ITO) (ITO/Al/ITO), or an APC alloy, and can be formed as a single layer or multiple layers, but the embodiments of the present disclosure are not limited thereto.

The organic layer 152 can be disposed on the first electrode 151. The organic layer 152 can include one or more light-emitting structures (or light-emitting elements or elements) laminated in the order or reverse order of a hole transport layer and an electron transport layer on the first electrode 151. The organic layer 152 can be an organic light-emitting layer, an inorganic light-emitting layer, a quantum dot light-emitting layer, a micro light-emitting diode, or a micro mini light-emitting diode, but is not limited thereto. For example, the organic layer 152 of the display panel 100 according to one embodiment of the present disclosure can include an organic light-emitting layer. The organic layer 152 can include a red light-emitting layer, a green light-emitting layer, and a blue light-emitting layer.

The second electrode 153 can be disposed on the organic layer 152. The second electrode 153 can be a transparent electrode that transmits light, but is not limited thereto. For example, the second electrode 153 can include a transparent conductive material such as ITO (Indium Tin Oxide) or IZO (Indium Zinc Oxide), or a metal that transmits visible light.

The bank 154 can be disposed to expose the first electrode 151. The bank 154 can define an opening (or light-emitting area) of the sub-pixel and can be disposed to cover an edge portion of the first electrode 151. Each of the plurality of sub-pixels can include a red light-emitting area, a green light-emitting area, and a blue light-emitting area.

A spacer 155 can be further disposed on the bank 154.

The encapsulation unit 170 can be disposed on the bank 154 or the light-emitting unit 150. The encapsulation unit 170 can include one or more insulating layers. For example, the encapsulation unit 170 can include a first encapsulation layer 171, a second encapsulation layer 172 disposed on the first encapsulation layer 171, and a third encapsulation layer 173 disposed on the second encapsulation layer 172. The encapsulation unit 170 can include one or more inorganic material layers and one or more organic material layers. For example, the first encapsulation layer 171 and the third encapsulation layer 173 can include an inorganic material, and the second encapsulation layer 172 can include an organic material.

A touch buffer layer 181 can be disposed on the encapsulation unit 170. For example, the touch buffer layer 181 can be disposed on the third encapsulation layer 173. The touch buffer layer 181 can be made of the same material as the buffer layer 102. A first touch conductive layer can be disposed on the touch buffer layer 181. A first touch insulating layer 183 can be disposed on the first touch conductive layer. The first touch insulating layer 183 can prevent short circuits between touch electrodes. The first touch insulating layer 183 can include an organic or inorganic material. A second touch conductive layer can be disposed on the first touch insulating layer 183.

The first touch conductive layer can include a second touch electrode 182, and the second touch conductive layer can include a first touch electrode 185. The first touch electrode 185 can include a 1a touch electrode 185a extending in a first direction and a 1b touch electrode 185b extending in a second direction different from the first direction. In FIG. 6 , the first touch electrode 185 and the second touch electrode 182 are illustrated overlapping the light-emitting area, but the first and second touch electrodes 185, 182 can each be arranged to overlap the bank 154.

The second touch electrode 182 can be electrically connected to the 1a touch electrode 185a through a contact hole formed in the first touch insulating layer 183. For example, the 1a touch electrode 185a and the second touch electrode 182 can extend in the first direction.

The first touch electrode 185 and the second touch electrode 182 can include a metal material. For example, the first touch electrode 185 and the second touch electrode 182 can be made of titanium (Ti), nickel (Ni), aluminum (Al), or an alloy thereof, and can be made of a triple layer such as titanium (Ti)/aluminum (Al)/titanium (Ti), but the embodiments of the present disclosure are not limited thereto.

A second touch insulating layer 184 can be disposed on the second touch conductive layer. The second touch insulating layer 184 can include an organic material.

An upper organic layer 190 can be disposed on the touch unit 180, but the embodiments of the present disclosure are not limited thereto. The upper organic layer 190 can include an organic material.

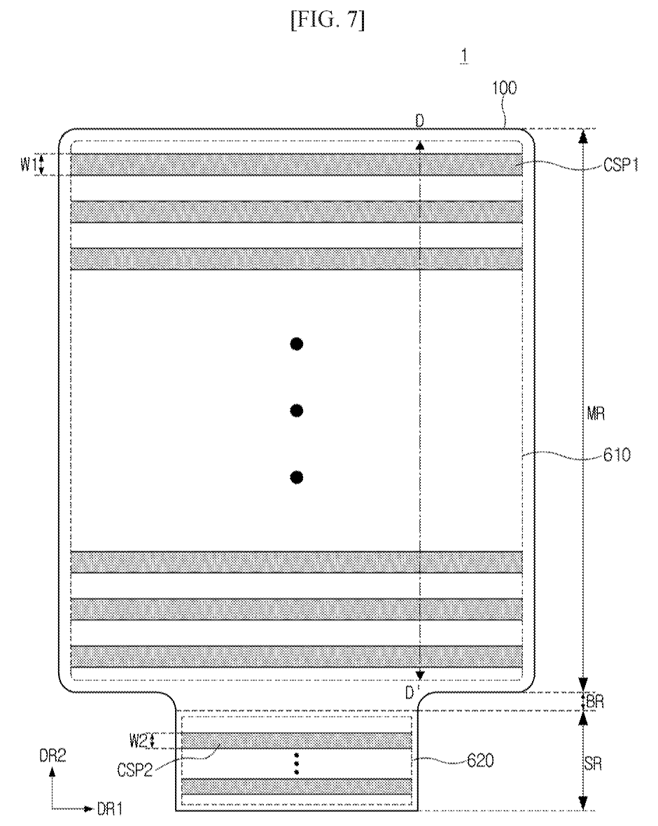

FIG. 7 is a schematic plan view of a display device according to one embodiment of the present disclosure.

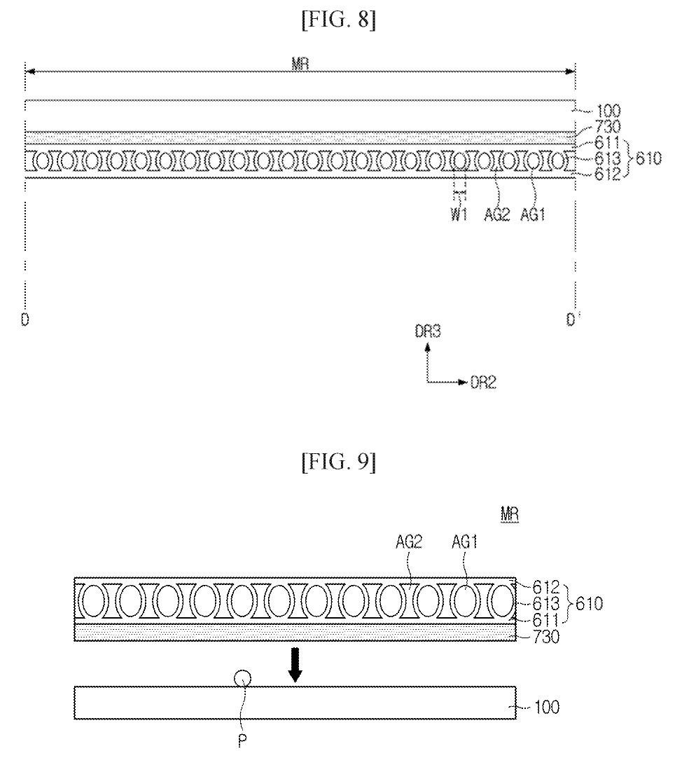

Referring to FIG. 7, the display device 1 according to one embodiment of the present disclosure can include a first backplate layer 610 disposed in the main region (MR) and the second backplate layer 620 disposed in the sub region (SR). The first backplate layer 610 can include a first pattern (CSP1) extending along a first direction (DR1), and the second backplate layer 620 can include a second pattern (CSP2) extending along the first direction (DR1). The extension direction of each of first and second patterns (CSP1, CSP2) can be the same as the extension direction of the bending region (BR). The first pattern (CSP1) can be provided in multiple numbers and spaced apart from each other along the second direction (DR2), and the second pattern (CSP2) can be provided in multiple numbers and spaced apart from each other along the second direction (DR2). Each of first and second patterns (CSP1, CSP2) can correspond to a first air gap (AG1) described in FIG. 8.

In some embodiments of the present disclosure, the extension direction of each of first and second patterns (CSP1, CSP2) can be in the second direction (DR2), and the first patterns (CSP1) can be spaced apart in the first direction (DR1), and the second patterns (CSP2) can be spaced apart in the first direction (DR1).

The first pattern (CSP1) can have a first width (W1), and the second pattern (CSP2) can have a second width (W2). The first width (W1) and the second width (W2) can be the same.

In some embodiments of the present disclosure, the first width (W1) can be greater than the second width (W2). As described below, the first and second backplate layers 610, 620 can each absorb impact or external force applied to the display panel 100, thereby preventing or minimizing the display panel 100 from being damaged. Furthermore, in the case of a bent display device 1, the first backplate layer 610 can be positioned closer to the display panel 100 than the second backplate layer 620. The first and second patterns (CSP1, CSP2) can absorb impact or external force applied to each of the first and second backplate layers 610, 620, and as described above, since the first backplate layer 610 is positioned closer to the display panel 100 than the second backplate layer 620, the first width (W1) of the first pattern (CSP1) can be larger than the second width (W2) of the second pattern (CSP2).

FIG. 8 is a cross-sectional view taken along the line D-D’ of FIG. 7. For example, FIG. 8 illustrates the cross-sectional structure of the display panel 100, the first backplate layer 610, and the third bonding layer 730 of FIG. 7. Although only the cross-sectional structure of the first backplate layer 610 is illustrated in FIG. 8, the cross-sectional structure of the second backplate layer 620 can be the same as the cross-sectional structure of the first backplate layer 610.

Referring to FIGS. 7 and 8, the first backplate layer 610 can include a first base layer 611, a second base layer 612, and an elastic layer 613. The first base layer 611 can be disposed between the third bonding layer 730 and the second base layer 612, and can be directly connected to the third bonding layer 730. The second base layer 612 can face the first base layer 611. The elastic layer 613 is disposed between the first base layer 611 and the second base layer 612, and can be in direct contact with the adjacent first and second base layers 611, 612. The cross-sectional shape of the elastic layer 613 can be circular or elliptical, but the embodiments of the present disclosure are not limited thereto.

The first air gap (AG1) can be disposed inside the elastic layer 613. The first air gap (AG1) can have the same configuration as the first and second patterns (CSP1, CSP2) described above in FIG. 7. The first air gap (AG1) can be completely surrounded by the elastic layer 613. The elastic layers 613 can be provided in multiple numbers and can be disposed spaced apart from each other along the second direction (DR2). A second air gap (AG2) can be disposed between adjacent elastic layers 613. The second air gap (AG2) can be completely surrounded by adjacent elastic layers 613, the first base layer 611, and the second base layer 612.

According to one embodiment of the present disclosure, the first base layer 611, the second base layer 612, and the elastic layer 613 can be formed integrally and can comprise the same material. For example, the first base layer 611, the second base layer 612, and the elastic layer 613 can comprise polyethylene terephthalate (PET), polyimide (PI), or polycarbonate (PC), but the embodiments of the present disclosure are not limited thereto.

Hereinafter, the function of the first backplate layer 610 according to one embodiment of the present disclosure to absorb impact or external force applied to the display panel 100 will be described.

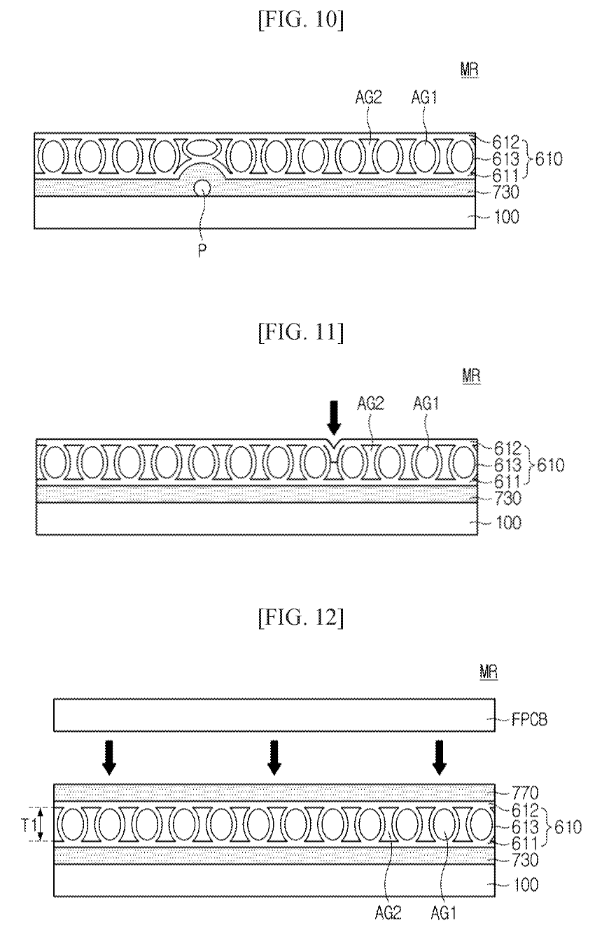

FIGS. 9 and 10 are cross-sectional views showing the absorption of impact caused by foreign substances in a display device according to one embodiment of the present disclosure. For example, FIGS. 9 and 10 show a process of attaching a first backplate layer 610 to the display panel 100.

Referring to FIG. 9, a foreign substance (P) can be placed on the surface of the display panel 100 (the lower surface of the display panel 100 based on FIG. 4).

Referring to FIG. 10, when attaching the first backplate layer 610 to the display panel 100 via the third bonding layer 730, if the elasticity of the first backplate layer 610 is low, an impact can be transmitted to the display panel 100 by the foreign substance (P), causing damage to the display panel 100. However, in one embodiment of the present disclosure, the first backplate layer 610 can have elasticity due to the first air gap (AG1) and the second air gap (AG2). Accordingly, as illustrated in FIG. 10, the first base layer 611 rises along the step of the foreign substance (P), and the first air gap (AG1) and/or the second air gap (AG2) is reduced by the space where the first base layer 611 rises, thereby absorbing the impact caused by the foreign substance (P).

FIG. 11 is a cross-sectional view illustrating the absorption of external force by a display device according to one embodiment of the present disclosure.

Referring to FIG. 11, an external force can be applied from the upper direction of the first backplate layer 610. If the elasticity of the first backplate layer 610 is low, the external force can be applied to the display panel 100, damaging the display panel 100.

However, according to one embodiment of the present disclosure, when an external force is applied, the second base layer 612 can fill the second air gap (AG2) located at the point where the external force is applied, thereby coming into contact with the side surfaces of adjacent elastic layers 613. For example, since the first backplate layer 610 absorbs the external force while being deformed, the external force is not applied to the display panel 100, thereby preventing or minimizing damage to the display panel 100.

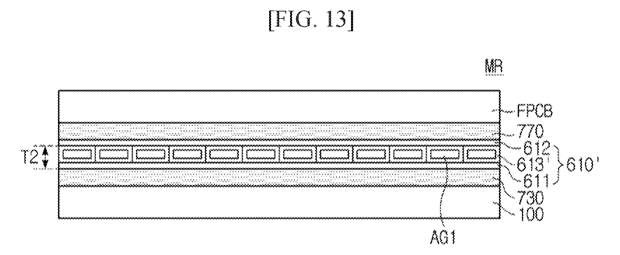

FIGS. 12 and 13 are cross-sectional views illustrating the absorption of an external force generated during the process of attaching a printed circuit board by a display device according to one embodiment of the present disclosure.

Referring to FIG. 12, as described above with reference to FIG. 4, the printed circuit board (FPCB) can be attached to the first backplate layer 610 via the seventh bonding layer 770. Before the printed circuit board (FPCB) comes into contact with the seventh bonding layer 770, the elastic layer 613 of the first backplate layer 610 can have a first thickness (T1) and may not be deformed.

Referring to FIG. 13, when the printed circuit board (FPCB) is attached to the seventh bonding layer 770, the elastic layer 613' of the first backplate layer 610' can be deformed to have a second thickness (T2) smaller than the first thickness (T1). In addition, the cross-sectional structure of the elastic layer 613' can be widened according to the second thickness (T2). Therefore, the cross-sectional structure of the first air gap (AG1) can have a rectangular shape. As illustrated in FIG. 13, since the first backplate layer 610' absorbs an external force, adjacent elastic layers 613' can directly contact each other. For example, the second air gap (AG2) of FIG. 12 can be filled with elastic layers 613'.

For example, even during the process of attaching a printed circuit board (FPCB), the first backplate layer 610 has a structure capable of withstanding an external force for attaching the printed circuit board (FPCB), thereby preventing or minimizing the external force from being transmitted to the display panel 100, thereby preventing or minimizing damage to the display panel 100.

According to an embodiment of the present disclosure, the display device includes a display panel; and a backplate layer disposed on a lower surface of the display panel, and the backplate layer includes an air gap surrounded by the backplate layer.

In the display device according to the embodiments of the present disclosure, the backplate layer can include a first base layer; a second base layer facing the first base layer; and an elastic layer between the first base layer and the second base layer.

In the display device according to the embodiments of the present disclosure, the air gap can be disposed between adjacent elastic layers and within the elastic layer.

In the display device according to the embodiments of the present disclosure, the air gap can include a first air gap completely surrounded by the elastic layer; and a second air gap completely surrounded by the first base layer, the second base layer, and the adjacent elastic layers.

In the display device according to the embodiments of the present disclosure, the first base layer, the second base layer, and the elastic layer can be integrally formed.

In the display device according to the embodiments of the present disclosure, the first base layer, the second base layer, and the elastic layer can include the same material.

According to the embodiments of the present disclosure, the air gap can be completely surrounded by the backplate layer.

In the display device according to the embodiments of the present disclosure, the display panel can include main region, a sub-region, and a bending region, and the backplate layer comprises a first backplate layer on a lower surface of the main region, and a second backplate layer on a lower surface of the sub-region.

In the display device according to the embodiments of the present disclosure, the first backplate layer and the second backplate layer each can include the air gap therein.

In the display device according to the embodiments of the present disclosure, the backplate layer can include a first base layer, a second base layer facing the first base layer, and an elastic layer between the first base layer and the second base layer, and an extension direction of the elastic layer can be the same as an extension direction of the bending region.

In another aspect, a display device according to the embodiments of the present disclosure can include a display panel comprising a main region, a sub-region, and a bending region; a first backplate layer disposed on a lower surface of the main region of the display panel; a second backplate layer disposed on a lower surface of the sub-region of the display panel; and a mold portion disposed on a lower surface of the bending region of the display panel, and the first backplate layer or the second backplate layer can include an air gap therein, and the mold portion can contact the first backplate layer.

In the display device according to the embodiments of the present disclosure, each of the first backplate layer and the second backplate layer can include a first base layer; a second base layer facing the first base layer; and an elastic layer between the first base layer and the second base layer.

In the display device according to the embodiments of the present disclosure, the air gap can be disposed between adjacent elastic layers and within the elastic layer.

In the display device according to the embodiments of the present disclosure, the air gap can include a first air gap completely surrounded by the elastic layer; and a second air gap completely surrounded by the first base layer, the second base layer, and adjacent elastic layers.

In the display device according to the embodiments of the present disclosure, the first base layer, the second base layer, and the elastic layer can be integrally formed.

In the display device according to the embodiments of the present disclosure, the first base layer, the second base layer, and the elastic layer can include the same material.

In the display device according to the embodiments of the present disclosure, the mold portion can contact at least one of the first base layer, the second base layer, and the elastic layer.

The display device according to the embodiments of the present disclosure can further include a cover layer disposed on an upper surface of the bending region of the display panel, and the mold portion can be further disposed on an upper surface of the cover layer.

The display device according to the embodiments of the present disclosure can further include a polarizing layer disposed on an upper surface of the main region of the display panel, and the polarizing layer can contact the cover layer.

The display device according to the embodiments of the present disclosure can include a printed circuit board attached to an upper surface of the sub-region of the display panel, and the printed circuit board can be attached to a lower surface of the first backplate layer through a bonding layer.

Although the embodiments of the present disclosure have been described with reference to the accompanying drawings, it will be understood by those skilled in the art to which the present disclosure pertains that the technical configuration of the present disclosure described above can be implemented in other specific forms without departing from the technical spirit or essential features thereof. Therefore, it should be understood that the embodiments of the present disclosure described above are illustrative in all respects and not restrictive. Furthermore, the scope of the present disclosure is defined by the following claims rather than the detailed description. In addition, all changes or modifications derived from the meaning and scope of the claims and their equivalent concepts should be interpreted as being included within the scope of the present disclosure.

What is claimed is:

1. A display device comprising:
a display panel; and
a backplate layer disposed on a lower surface of the display panel,
wherein the backplate layer comprises an air gap formed therein, the air gap being completely surrounded by the backplate layer.

2. The display device of claim 1, wherein the backplate layer comprises:
a first base layer;
a second base layer facing the first base layer; and
an elastic layer between the first base layer and the second base layer.

3. The display device of claim 2, wherein the air gap is disposed between adjacent elastic layers and within the elastic layer.

4. The display device of claim 3, wherein the air gap comprises:
a first air gap completely surrounded by the elastic layer; and
a second air gap completely surrounded by the first base layer, the second base layer, and the adjacent elastic layers.

5. The display device of claim 2, wherein the first base layer, the second base layer, and the elastic layer are integrally formed.

6. The display device of claim 2, wherein the first base layer, the second base layer, and the elastic layer comprise a same material.

7. The display device of claim 1, wherein the display panel comprises a main region, a sub-region, and a bending region, and
the backplate layer comprises a first backplate layer on a lower surface of the main region, and a second backplate layer on a lower surface of the sub-region.

8. The display device of claim 7, wherein the first backplate layer and the second backplate layer each comprise the air gap therein.

9. The display device of claim 8, wherein the backplate layer comprises a first base layer, a second base layer facing the first base layer, and an elastic layer between the first base layer and the second base layer, and
an extension direction of the elastic layer is the same as an extension direction of the bending region.

10. The display device of claim 7, wherein the first backplate layer includes a first pattern extending along a specific direction, and the second backplate layer includes a second pattern extending along the specific direction, and
the first pattern has a width that is greater than or same as a width of the second pattern.

11. A display device comprising:
a display panel comprising a main region, a sub-region, and a bending region;
a first backplate layer disposed on a lower surface of the main region of the display panel;
a second backplate layer disposed on a lower surface of the sub-region of the display panel; and
a mold portion disposed on a lower surface of the bending region of the display panel,
wherein the first backplate layer or the second backplate layer comprises an air gap therein, and
wherein the mold portion contacts the first backplate layer.

12. The display device of claim 11, wherein each of the first backplate layer and the second backplate layer comprises:
a first base layer;
a second base layer facing the first base layer; and
an elastic layer between the first base layer and the second base layer.

13. The display device of claim 12, wherein the air gap is disposed between adjacent elastic layers and within the elastic layer.

14. The display device of claim 13, wherein the air gap comprises:
a first air gap completely surrounded by the elastic layer; and
a second air gap completely surrounded by the first base layer, the second base layer, and adjacent elastic layers.

15. The display device of claim 12, wherein the first base layer, the second base layer, and the elastic layer are integrally formed.

16. The display device of claim 12, wherein the first base layer, the second base layer, and the elastic layer comprise a same material.

17. The display device of claim 12, wherein the mold portion contacts at least one of the first base layer, the second base layer, and the elastic layer.

18. The display device of claim 11, further comprising:
a cover layer disposed on an upper surface of the bending region of the display panel,
wherein the mold portion is disposed on an upper surface of the cover layer.

19. The display device of claim 18, further comprising:
a polarizing layer disposed on an upper surface of the main region of the display panel,
wherein the polarizing layer contacts the cover layer.

20. The display device of claim 11, further comprising:
a printed circuit board attached to an upper surface of the sub-region of the display panel,
wherein the printed circuit board is attached to a lower surface of the first backplate layer through a bonding layer.
